(19) United States
(12) Patent Application Publication
(10) Pub. No.: US 2012/0025376 A1
(43) Pub. Date: Feb. 2, 2012

(54) BALL GRID ARRAY PACKAGE

(75) Inventors: TING LIANG, Shanghai (CN); YAN QI, Shanghai (CN)

(73) Assignees: HON HAI PRECISION INDUSTRY CO., LTD., Tu-Cheng (TW); AMBIT MICROSYSTEMS (SHANGHAI) LTD., SHANGHAI (CN)

(21) Appl. No.: 12/916,645

(22) Filed: Nov. 1, 2010

(30) Foreign Application Priority Data
Jul. 30, 2010 (CN) 201020277093.X

(51) Int. Cl. H01L 23/498

(52) U.S. Cl. 257/738; 257/E23.069

(57) ABSTRACT

A BGA package includes an IC die, a substrate, a plurality of solder balls, and a square contact pad. The portions of the contact pad capable of interfering with the IC die are removed to ensure the space between two of the contact pads is sufficient to avoid noise interference.

### BACKGROUND

1. Technical Field

The present disclosure relates to a ball grid array (BGA) solder pad and a chip package with the BGA pad, and more particularly to a BGA solder pad for bonding with capacitors and BGA package chip with the solder pad.

2. Description of Related Art

The consumer electronics industry will be determined by their ability to deliver increasingly miniaturized products at lower costs. A BGA package achieves these objectives by providing increased functionality for the same package size while being compatible with existing surface mount technology (SMT) infrastructure. In common BGA layout design, electrically coupling a capacitor with each power supply line of a packaged integrated circuit (IC) can implement filter function for unwanted electrical noise. However, it is difficult to implement when the BGA chip package is within a smaller package or the space between two vias is limited.

### BRIEF DESCRIPTION OF THE DRAWINGS

FIG. 1 is a schematic structural diagram of a BGA package of the present disclosure.

FIG. 2 is a backward schematic diagram of one embodiment of BGA package of the present disclosure.

### DETAILED DESCRIPTION

The invention is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

Note that the terms “contact pad,” “contact,” and “conductive pad” are used interchangeably herein to refer to an element that makes electrical contact between two corresponding elements. Furthermore, as used herein, “array” refers to a group of combination of conductive pads or pins on a surface of a PCB or substrate. For example, “array” is used to refer to a group or combination of conductive pads or pins of an IC package substrate, typically arranged in rows and columns, for interfacing with a PCB or other structure, when mounted thereto. As used herein, “land pattern” refers to a type of array, primarily referring to a group or combination of conductive pads on a surface of a PCB or other structure, typically arranged in rows and columns, intended for the mounting of an integrated circuit (IC) package/die. A “land pattern” is also known as “footprint,” and these terms are used interchangeably herein. Vias, or plated through holes, are used in multi-layer PCBs to transfer signals from one layer to another. Vias are actual holes drilled through a multi-layer PCB and provide electrical connections between various PCB layers. All vias provide layer-to-layer connections only. Device leads or other reinforcing materials are not inserted into vias.

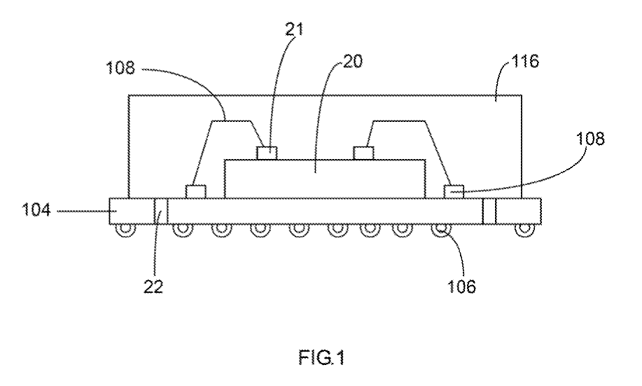

FIG. 1 illustrates a schematic structural diagram of a BGA package 100 of the present disclosure. The BGA package 100 includes an IC die 20, a substrate 104, a plurality of solder balls 106, and one or more wire bonds 108.

The substrate 104 is generally made from one or more conductive layers bonded with a dielectric material. For instance, the dielectric material may be various substances, such as polyimide tape. Tape (or “flex”) substrates are particularly appropriate for large IC dies with large numbers of inputs and outputs, such as application specific integrated circuits (ASIC) and microprocessors. The conductive layers are typically metal, or a combination of metals, such as copper and/or aluminum. Trace or routing patterns are formed in the conductive layer material. Substrate 104 may be a single-layer tape, a two-layer tape, or additional layer tape substrate type. In a two-layer tape, the metal layers sandwich the dielectric layer, such as in a copper-Upilex-copper arrangement. The Substrate 104 may alternatively be a plastic, ceramic, or other substrate type.

The IC die 20 is attached directly to the substrate 104, for example, by an epoxy or other die-attaching material. The IC die 20 is any type of semiconductor integrated circuit, separated from a semiconductor wafer.

One or more wire bonds 108 connect corresponding bond pads 118 on the IC die 20 to contact pads 23 on the substrate 104. Bond pads 118 are I/O pads for the IC die 20 that make internal signals of the IC die 20 externally available. Note that alternatively, the IC die 20 may be flipped and mounted to substrate 104 by solder balls located on the bottom surface of the IC die 20, by a process commonly referred to as “C4” or “flip chip” packaging. In such an embodiment, wire bonds 108 are not required.

Encapsulating material 116 covers the IC die 20 and wire bonds 108 for mechanical and environmental protection. The encapsulating material 116 is a mold compound, epoxy, or other applicable encapsulating substance.

The BGA package 100 includes an array of solder ball pads located on a bottom external surface of the substrate 104 for attachment of solder balls 106. The wire bonds 108 are electrically connected to solder balls 106 underneath the substrate 104 through corresponding vias 22 and routing in the substrate 104. The vias 22 in the substrate 104 can be plated or filled with a conductive material, such as solder, to allow for these connections. Solder balls 106 are used to attach the BGA package 100 to the PCB.

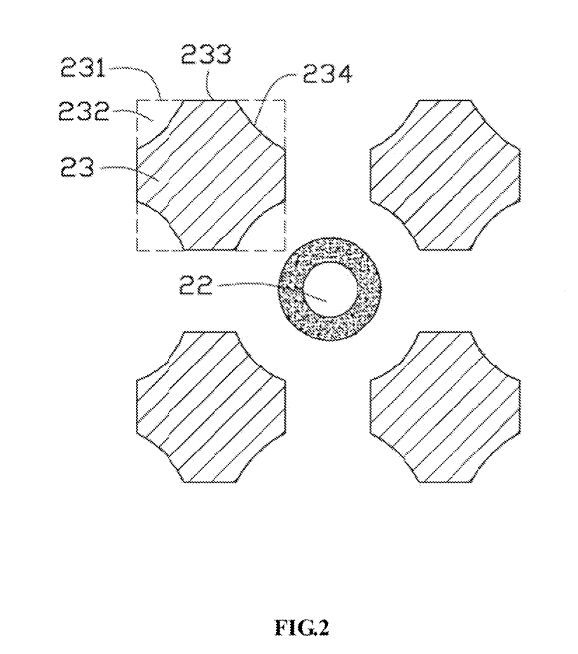

FIG. 2 is a backward schematic diagram of one embodiment of BGA package 100 of the present disclosure. The contact pads 23 are disposed on the opposite of the IC die 20 to electrically couple with filter capacitors. The filter capacitor coupled with the contact pad 23 electrically connects with the power pins 21 through the vias 22. Since some portions of the contact pad 23 block a large area of the substrate 104, the arrangement of the vias 22 is interfered. As a result, not each filter capacitors can electrically connect with ground. Those without grounding capacitors are may leak capacitance state and filtering efficiency of filter capacitors is significantly reduced. Therefore, in one embodiment, portions of the contact pad 23 that capable of interfering with the power pins 21 and reduce efficiency of the filter capacitors, are removed to ensure the distance between the contact pad 23 and the edges of the contact pad 23 is sufficient to avoid such interference.

In one embodiment, each of the contact pads 23 has a square-like shape, consisting of a square 231 with four sector regions at the four corners of the square 231 are removed. The contact pad 23 has 2 edges 233, shaped as a beeline, and 2 edges 234, shaped as curves. The two edges 233 are correspondingly opposite to each other. The 2 curve edges 234 are correspondingly opposite from each other. The edges 233 and edges 234 are arranged in a predefined interval. In one embodiment, the predefined interval is arranged as one edge 233 next to edge 234 in sequence, and the central point of each edge 234 is towards to one of the vias 22 in the vicinity of the edge 234. A space between the vias 22 and the edges 234 is maintained to ensure the arrangement of filter capacitors disposed on the contact pads 23 is efficient.

In one embodiment, the length of the edges 233 is about 0.22 mm and height of the contact pad 23 is about 1 mm. Distance from center of the contact pad 23 to center of a neighboring contact pad 23 is about 1 mm.

It should be noted that the descriptions of size and magnitude of the contact pads 23 is not intended to limit, but simply serve explanation of this disclose. Portions of the contact pad 23, which are capable of causing interferences with the power pins 21 and reduces the efficiency of the filter capacitors, are removed to ensure each power pin 21 is capable of electrically coupling to at least one filer capacitor with sufficient space. Thus, the density of the filter capacitors disposed on the BGA package 100 can be raised to increase the stability of power supply for the IC die 20 attached in the BGA package 100.

Although certain inventive embodiments of the present disclosure have been specifically described, the present disclosure is not to be construed as being limited thereto. Various changes or modifications may be made to the present disclosure without departing from the scope and spirit of the present disclosure.

What is claimed is:

1. A ball grid array package, comprising:
a substrate;
an integrated circuit (IC) die disposed with the substrate;
a plurality of solder balls, wherein the IC die is electrically coupled with the substrate through the solder balls; and
a plurality of square contact pad, wherein portions of the contact pads that are capable of interfering with the IC die, are removed.

2. The ball grid array package of claim 1, wherein the removed portions are four sector regions at the four corners of the square contact pads.

3. The ball grid array package of claim 2, wherein the square contact pads have two beeline edges and two curve edges, and the two beeline edges and the two curve edges are arranged as a predefined interval.

4. The ball grid array package of claim 3, wherein the predefined interval is arranged as one beeline edge next to one curve edge alternation.

5. The ball grid array package of claim 2, wherein the length of the beeline edges is about 0.22 mm.

6. The ball grid array package of claim 1, wherein the height of the contact pads is about 1 mm.

7. The ball grid array package of claim 2, wherein a space between two contact pads with the removed portions is enough for disposing a filter capacitor therebetween.
